(19) United States
(12) Patent Application Publication
(10) Pub. No.: US 2021/0110992 A1
(43) Pub. Date: Apr. 15, 2021

(54) IMAGE COLLECTION SYSTEM

(71) Applicant: HITACHI, LTD., Tokyo (JP)

(72) Inventors: Yoshio TAKAHASHI, Tokyo (JP); Tetsuya AKASHI, Tokyo (JP)

(73) Assignee: HITACHI, LTD., Tokyo (JP)

(21) Appl. No.: 17/061,671

(22) Filed: Oct. 2, 2020

(30) Foreign Application Priority Data
Oct. 10, 2019 (JP) 2019-186783

(51) Int. Cl. H01J 37/22; H01J 37/244

(52) U.S. Cl. CPC H01J 37/222; H01J 37/244

(57) ABSTRACT

In an image collection system using a transmission electron microscope, a useless collection time to be spent collecting images in each of which particles overlap each other or no particle is contained, and a date volume are reduced. The image collection system includes: a control unit that moves an observation field of view in the transmission electron microscope and overlaps each other electron waves that propagate through spatially different portions within the observation field of view; a photographing unit that acquires the overlapped electron waves as an observation image; and a determination unit that determines whether a particle is present within the observation field of view.

### BACKGROUND

The present invention relates to an image collection system using a transmission electron microscope.

A transmission electron microscope is a high-magnification microscope using electron beams. An electron generated in an electron source is accelerated by a high voltage of about 100 kV to 3000 kV, so that it is emitted to an observation sample and allowed to pass there through. The rays of the electrons that have passed through are magnified by lenses and detected by a camera, thereby obtaining a sample observation image. There is also an apparatus that can obtain a sample observation image at such a high magnification that the atoms that compose an observation sample can be identified.

When an electron to be emitted to a sample is regarded as a wave, the electron to pass through the sample can be considered as a wave having an amplitude component and a phase component. Since this phase component is changed by an influence of the electromagnetic field of an observation sample, information on the sample electromagnetic field can be obtained by detecting the phase of the electron wave. The information on a sample electromagnetic field means, for example, magnetic domain information inside a magnet, charge distribution information at a semiconductor interface, information on the average inner potential of nanoparticles, etc. An observation method for achieving this is an electron holography method. By attaching an interferometer known as an electron biprism to a transmission electron microscope, an electron wave that has passed through an object to be observed and a reference electron wave that serves as a phase reference are overlapped each other, whereby electron interference fringes (hologram) are formed and photographed by a camera. When this hologram is reconstructed, information on a phase change amount of the electron wave can be obtained as an image.

When the signal-to-noise ratio of information obtained by a transmission electron microscope is intended to be improved, it is necessary to increase a signal amount of a transmission electron microscope image. Therefore, an image is photographed by exposure for a long period, or a plurality of photographed images are added together. In observation at a high magnification, exposure for a long period decreases the resolution of an image due to a drift of a sample during the observation, and hence in many cases, an image is acquired by dividing into a plurality of photographed images and subsequently adding them together while matching positions. In observation of a sample likely to be damaged by an electron beam, the sample may be damaged and deformed while many images of it are photographed. In order to avoid this, in some cases, a large number of different sample objects having the same shape are provided and observed, and those acquired images are added together by aligning directions. In either case, a large number of electron microscope images are needed.

In a method known as a single particle analysis method using a transmission electron microscope, a large number of electron microscope images depicting proteins, viruses, and the like having the same shapes (they are collectively referred to particles) are observed, and regarding the particles, extraction, classification, aligning positions, integration, and three-dimensional construction are performed on a computer.

Also, in observation of a sample electromagnetic field by the electron holography method, the concept of the integration and averaging of the single particle analysis method is applied. For example, when an inner potential analysis is performed on metal nanop articles, a large number of holograms of a sample in which the metal nanoparticles are dispersed on a carbon film are photographed, and regarding the metal nanoparticles, extraction from a reconstructed phase image of the holograms, classification, aligning positions, and integration are performed, thereby improving the signal-to-noise ratio of the phase image.

Collection of images in a general electron microscope is performed by repeating a procedure in which an operator specifies an observation position, adjusts an observation condition, photographs an image, and stores the image. However, when a large number, over 1000 or so, of images are collected and when the collection is repeated manually, collection mistakes are increases by accumulation of fatigue due to long-hour work, so that the manual collection is not realistic. It is desirable that repetition of selecting an observation field of view, adjusting, photographing, and storing is performed automatically by a control system.

For example, Japanese Unexamined Patent Application Publication No. 2002-25491 discloses a system that, in collecting electron microscope images, adjusts an optical condition, moves a field of view, determines whether the field of view is suitable for observation, search for a pattern to be searched, and collects them automatically.

Japanese Unexamined Patent Application Publication No. 2004-253261 discloses a technology that, in collecting electron microscope images, automatically acquires a large number of images from a sample in fields of view different from each other, and for the acquired image, that determines whether there is a structure to be observed in the image, simultaneously with the acquisition of the image.

Further, Japanese Unexamined Patent Application Publication No. 2019-21524 discloses an automated collection system that, in collecting holograms by the electron holography method, repeats movement of field of view, hologram photographing, hologram storage, and adjustment of focus and astigmatism.

### SUMMARY

When an image of many particles is acquired by the electron holography method, it often happens that particles to be observed are not contained in the one photographed hologram, or that a plurality of particles overlapping each other are contained therein. Such a hologram cannot be used for integration or averaging of particles.

Since the technologies disclosed in Japanese Unexamined Patent Application Publication No. 2002-25491 and Japanese Unexamined Patent Application Publication No. 2004-253261 are not intended to be used in the electron holography method, an automated collection system, which reduces an image in which particles overlapping each other are contained or no particle is contained, in order to reduce a collection time and a data volume, is not achieved.

Additionally, Japanese Unexamined Patent Application Publication No. 2004-253261 determines, based on the edge, brightness, outer shape, etc., of a real image, whether or not there exist liposomes, but there is the possibility that an accurate determination on the presence or absence of particles cannot be made.

Additionally, the technology disclosed in Japanese Unexamined Patent Application Publication No. 2019-21524 relates to an automated collection system of electron hologram, but it is not intended to reduce a useless collection time to be spent collecting images in which particles overlapping each other are contained or no particle is observed, or reduce a data volume.

An object of the present invention is to reduce, in an image collection system using a transmission electron microscope, a useless collection time to be spent collecting images in which particles overlapping each other are contained or no particle is contained, and reduce a data volume.

An image collection system according to an aspect of the present invention is an image collection system using a transmission electron microscope, and the image collection system includes: a control unit that moves an observation field of view in the transmission electron microscope; a photographing unit that acquires an observation image by overlapping each other electron waves that have passed through the observation field of view with the use of the transmission electron microscope; and a determination unit that determines whether a particle is present within the observation field of view. The determination unit determines whether the particle is present, by acquiring a side band image in Fourier space of the observation image.

The image collection system according to an aspect of the present invention is an image collection system using a transmission electron microscope, and the image collection system includes: a control unit that moves an observation field of view in the transmission electron microscope in order to overlap each other electron waves that propagate through spatially different portions within the observation field of view; a photographing unit that acquires the overlapped electron waves as an observation image; and a determination unit that determines whether a particle is present within the observation field of view.

An image collection system according to an aspect of the present invention is an image collection system using a transmission electron microscope, and the image collection system includes: a control unit that moves an observation field of view in the transmission electron microscope, overlaps each other electron waves that propagate through spatially different portions within the observation field of view, and determines whether a particle is present within the observation field of view; a photographing unit that acquires an image; and a storage unit that stores the acquired image. The photographing unit acquires the overlapped electron waves as an electron interference fringe image, and the control unit determines whether the particle is present within the observation field of view, by using the electron interference fringe image, and determines whether it is necessary to store the image based on a result of determining whether the particle is present within the observation field of view. When it is necessary to store the image as a result of determining whether it is necessary to store the image, the photographing unit acquires a transmission electron microscope image within the observation field of view, and the control unit stores the acquired transmission electron microscope image in the storage unit.

According to an aspect of the present invention, in an image collection system using a transmission electron microscope, a useless collection time to be spent collecting images in which particles overlapping each other are contained or no particle is contained, and a data volume can be reduced.

### BRIEF DESCRIPTION OF THE DRAWINGS

FIG. 1 is a configuration view of an image collection system using a transmission electron microscope according to a first embodiment;

FIGS. 2A and 2B are images for explaining a sample to be provided for collecting a large number of particle images in a transmission electron microscope, and a field of view for forming a hologram, in which FIG. 2A is an entire image of the sample, and FIG. 2B is overlapped images in various places of the sample;

FIG. 3 is a flow chart of image collection in the image collection system according to the first embodiment;

FIG. 4 is a flow chart of image collection in an image collection system of a related technology;

FIGS. 5A to 5C are images for explaining the first embodiment, in which FIG. 5A is an image of an electron hologram of a particle portion, FIG. 5B is an image of a line profile of an electron hologram, and FIG. 5C is an image in which the phase of a particle is reconstructed;

FIG. 6A shows images for explaining the first embodiment, in which (a) is an image of a hologram, and (b) is an image in which the hologram is subjected to Fourier transform;

FIG. 6B shows images for explaining the first embodiment, in which (a) is an image of a center band portion of a Fourier-transformed hologram, and (b) is an image of a side band portion of the Fourier-transformed hologram;

FIG. 7 is a configuration view of an image collection system using a transmission electron microscope according to a second embodiment; and

FIG. 8 is a flow chart of image collection in an image collection system according to a third embodiment.

### DETAILED DESCRIPTION

When an image of a large number of particles is acquired in an electron holography method, it often happens that a particle to be observed is not contained or a plurality of particles overlapping each other are contained in one photographed hologram. Such a hologram cannot be used for integration or averaging of particles.

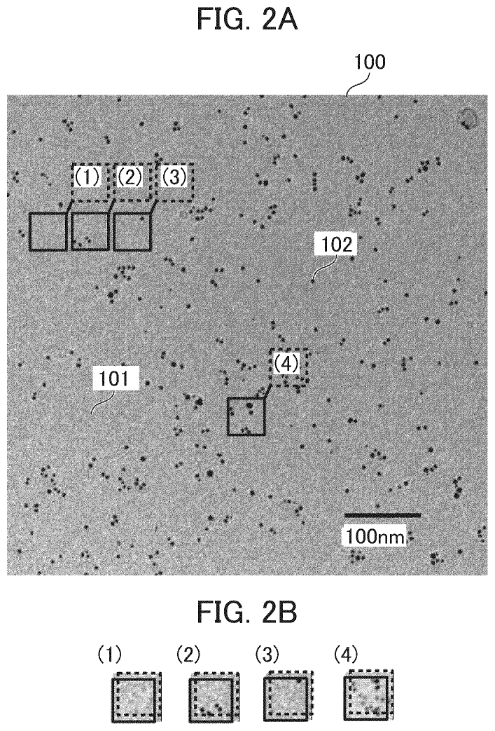

Specifically, holograms of a sample 100, in which as shown in FIG. 2A, gold nanoparticles 102 having a diameter of 5 nm are dispersed on a carbon film 101 such that an average of about one particle is contained within one field of view of the hologram, have been continuously collected.

First, an electron wave (object wave) that has passed through a solid-line square frame portion (1) of FIG. 2A and an electron wave (reference wave) that has passed through a broken-line square frame portion thereof are overlapped each other, and they are photographed as one overlapped image (hologram) as shown by (1) of FIG. 2B. After this image is stored, the observation field of view is moved to the position of (2) of FIG. 2A, and a hologram shown by (2) of FIG. 2B is obtained in the same way. By repeating this process so as to scan the sample 100, holograms within a wide range are obtained.

However, the hologram of (1) of FIG. 2B contains no particle to be observed, and the hologram of (4) of FIG. 2B contains particles to be observed that overlap each other. Such holograms cannot be used for integration or averaging of particles. When the inventor actually collected holograms for 10,000 fields of view, the holograms containing particles, which can be used, were only about 20 percent of the entire holograms. This means that 80 percent of each of the entire collection time and the volume of stored data is useless.

Specifically, the collection time for one field of view was 3.5 seconds and the size of the image was about 50 MB, and hence eight hours and 400 GB were useless. The reason why a large number of holograms that cannot be used are created is also because of an observation method in which in the electron holography, electron interference fringes are formed by overlapping an object wave and a reference wave each other. When a sample in which particles to be observed are dispersed is observed, an observation image in which particles are overlapped each other is obtained if particles are contained in both an object wave and a reference wave, creating a hologram that cannot be used. If particles are dispersed at a low particle density in order to avoid this, the probability that particles may not be contained in an object wave nor in a reference wave is increased, also creating many holograms that cannot be used.

In an image collection system using a transmission electron microscope, in the case where no sample object is contained within a field of view or where sample objects are excessively contained, the image for the field of view becomes unnecessary because the image for the field of view cannot be used, as described above, thereby making the image collection time useless.

The embodiments have been made in consideration of the above problem, and provide an image collection system of a transmission electron microscope, which can reduce, as a whole, an image collection time or the volume of stored data by avoiding photographing or storing an image that does not contain a particle to be observed or an image that cannot be used.

In order to solve the above problem, an image collection system using a transmission electron microscope according to an embodiment includes: a control unit that moves an observation field of view in the transmission electron microscope; a control unit that overlaps each other electron waves that propagate through spatially different portions within the observation field of view; a photographing unit that acquires the overlapped electron waves as an observation image; and a determination unit that determines that an object image to be photographed is contained in the observation image.

As one example, an image collection system using a transmission electron microscope according to an embodiment includes: a control unit that moves an observation field of view in the transmission electron microscope; a control unit that overlaps each other electron waves that propagate through spatially different portions within the observation field of view; a photographing unit that acquires the overlapped electron waves as an observation image; and a determination unit that determines that an object image to be photographed is contained in the observation image. The photographing unit photographs an electron interference fringe image, and the determination unit: calculates a Fourier-transformed image of the electron interference fringe image; extracts a side band image from the Fourier-transformed image; and determines that the object image to be photographed is contained in the observation image by using an image intensity peak position and an image intensity peak number of the side band image extracted from the Fourier-transformed image of a determination electron interference fringe image.

According to the embodiment, an image collection time or the volume of stored data can be reduced as a whole by reducing photographing or storing an image that does not contain an object to be observed or an image that cannot be used.

Hereinafter, embodiments of the present invention will be described with reference to the accompanying drawings. Although the accompanying drawings show specific embodiments in accordance with the principle of the present invention, they are shown for understanding the present application and are not used to construe the present invention in a limited manner.

### First Embodiment

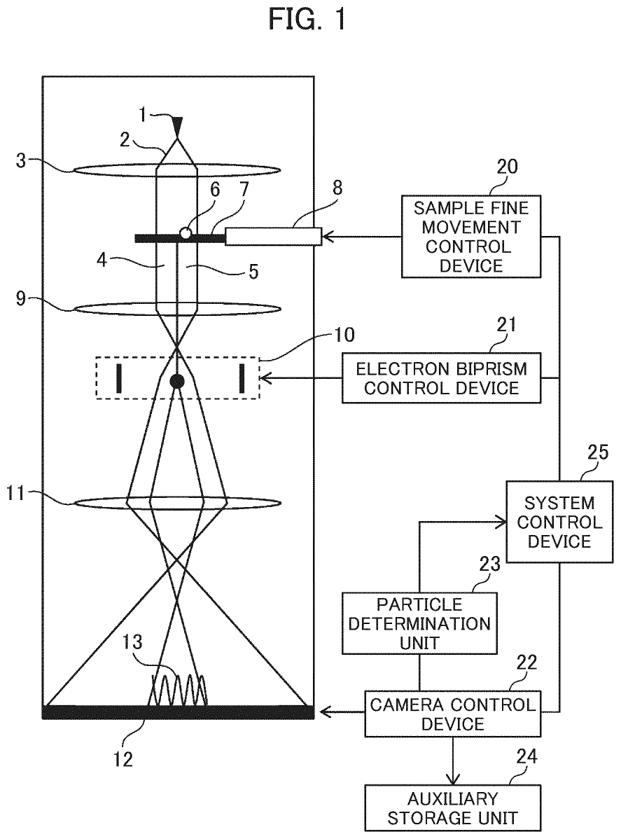

With reference to FIG. 1, a configuration of an image collection system using a transmission electron microscope according to a first embodiment will be described. FIG. 1 is a configuration view of an electron optical system, a ray of light, a control device, etc., which are used for performing image collection by an electron holography method in an image collection system of a transmission electron microscope.

A sample is irradiated with an electron beam 2 that has been emitted from an electron source 1, accelerated, and defined in size by an illumination lens 3. The sample, including a sample holding film 7, a sample object 6, etc., is placed in a sample fine movement device 8. The electron beam 2 passes through the sample (corresponding to 100 of FIG. 2A) including the sample object 6 (corresponding to 102 of FIG. 2A) and the sample holding film 7 (corresponding to 101 of FIG. 2A).

The electron beams 2 that have respectively passed through two spatially different portions of the sample are distinguished from each other as an object wave 5 and a reference wave 4. Although an objective lens 9 and a magnifying lens 11 cause the object wave 5 and the reference wave 4 to respectively form images on a camera 12, the images are overlapped each other on the camera 12 by an electron biprism 10 located downstream of the objective lens 9. Interference between electrons is created in the area where the images are overlapped, and electron interference fringes 13 are detected as an image by the detection with the camera 12. The sample fine movement device 8, to which the sample (the sample object 6 and the sample holding film 7) is attached, is controlled by a sample fine movement control device 20 such that an observation field of view is moved.

In the electron biprism 10, an amount of overlapping of the object wave 5 and the reference wave 4 and the spacing between the interference fringes are controlled by an electron biprism control device 21. A camera control device 22 controls photographing with the camera 12. A system control device 25 controls the sample fine movement control device 20, the electron biprism control device 21, and the camera control device 22 in order to control, in time series, the movement of field of view, the overlapping of electron waves, and the photographing with the camera. Upon receiving a signal from the camera control device 22, a particle determination unit 23 controls continuation of the photographing with the camera and storing an image in an auxiliary storage unit 24.

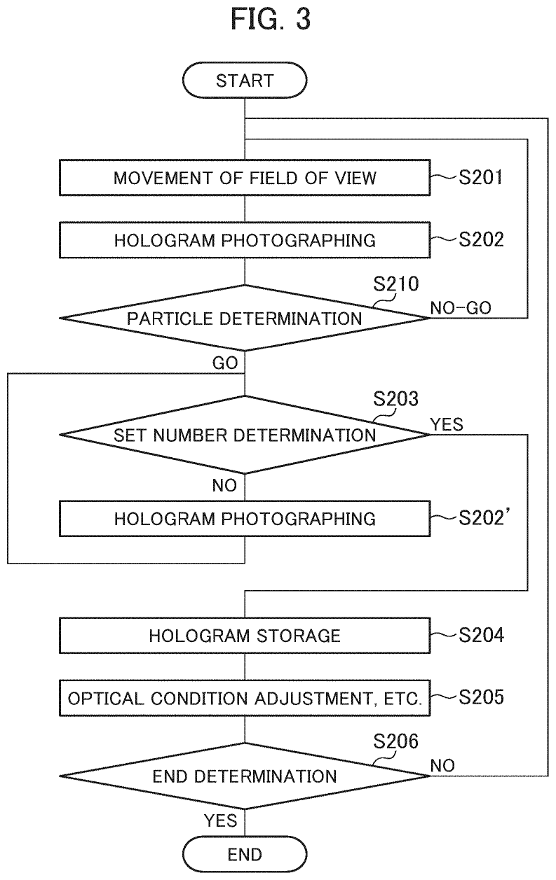

With reference to FIG. 3, an image collection flow in the image collection system according to the first embodiment will be described. When a large number of transmission electron microscope images or holograms are automatically collected, the image collection flow is controlled in time series by the system control device 25 of the transmission electron microscope image collection system shown in FIG. 1.

A sample used to collect a large number of holograms is the sample shown in FIG. 2A. The sample was produced in the following way: onto what had been made by attaching a micro grid to a 100 mesh (diameter of 3 mm) TEM grid made of copper and further by attaching a carbon film having a thickness of 15 nm thereto, gold nanoparticles having an average particle size of 5 nm and a standard deviation of 1 nm, which had been made by a citric acid reduction method and dispersed in distilled water at a concentration of 5×10¹⁶ particles/liter, were dropped by using a micropipette and then dried. In this sample, the carbon film having a thickness of 15 nm is the sample holding film 7, and the particles are the sample objects 6.

The sample is placed in the transmission electron microscope, and initial adjustment work for the transmission electron microscope, such as application of an acceleration voltage and adjustment of lenses, is done. After an observation site of the sample is determined, movement of field of view is performed (S201) at first according to the flow shown in FIG. 3.

When the sample shown in FIG. 2A is divided into a 20×20 grid pattern, areas each having a size of about 30 nm×30 nm are obtained, and the sample is moved such that each division of the sample is sequentially observed by the movement of field of view (S201). The movement may include horizontal raster scan, vertical raster scan, or spiral scan in a spiral manner. It is not necessary to accurately move the field of view according to the size of the divided division, and adjacent fields of view may overlap each other, or there may be a gap between them. A unit for moving a field of view is the sample fine movement device 8 shown in FIG. 1.

Next, hologram photographing is performed (S202). For one field of view, one or more images of a hologram are photographed. The reason why a plurality of images are photographed is because it is avoided that when an exposure time to be set for one field of view is long, an image may be blurred by being affected by a drift. The blurring of an image is reduced by photographing a plurality of images of a hologram and subsequently by adding the images together with drift correction (misalignment correction). At this time, after the first hologram photographing (S202), particle determination is made, in which it is determined whether a particle to be observed is contained in the hologram, whether too many particles are not contained, or the like (S210).

As a result of the determination, if it is determined as No-Go, the flow returns to the movement of field of view (S201); if it is determined as Gₒ, set number determination is made (S203), in which it is determined whether the set number of images have already been photographed; and if it is determined as No, the flow proceeds to hologram photographing (S202′). It is determined whether the set number of images of the hologram have already been photographed, by repeating the set number determination (S203) and the hologram photographing (S202′). When the set number determination (S203) becomes Yes determination, the flow proceeds to the next step.

Next, the photographed holograms are stored, as hologram storage (S204), in the auxiliary storage units 24 (see FIG. 1) such as a hard disk drive or a solid state drive.

Next, optical condition adjustment, etc., for the transmission electron microscope are performed (S205). Here, the optical condition adjustment, etc. (205) include correction of a focus deviation amount into a proper range, correction of astigmatism, correction of drift of an electron biprism, correction of illumination beam position, etc.

Finally, end determination is performed (S206), in which it is determined whether an end condition of the collection flow is satisfied. If it is satisfied, it is determined as Yes and the collection flow ends. If it not satisfied and is determined as No, the flow returns to the movement of field of view (S201) again and hologram collection is repeated.

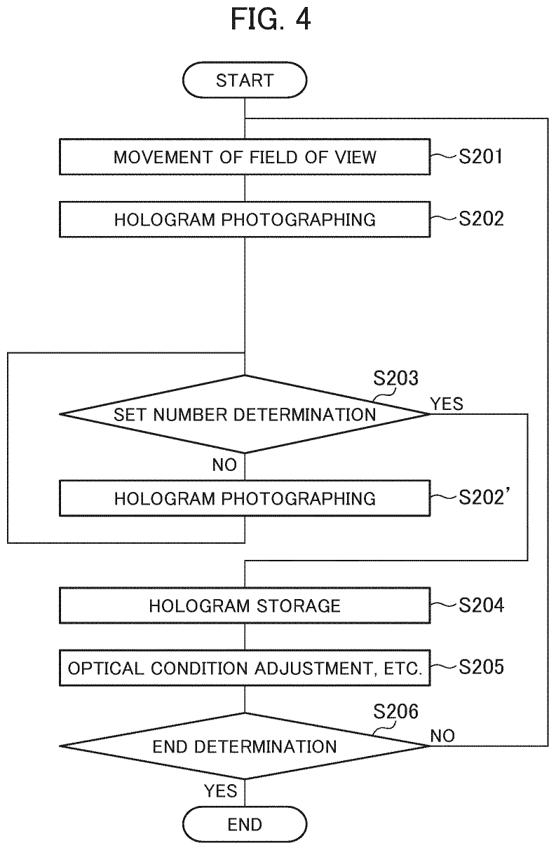

Here, an image collection flow in an image collection system according to a related technology will be described with reference to FIG. 4. For example, the sample shown in FIG. 2A is divided into a grid pattern, and movement of field of view is performed such that its one division can be sequentially observed (S201). The movement may include horizontal raster scan, vertical raster scan, or spiral scan in a spiral manner.

Next, hologram photographing is performed (S202). For one field of view, one or more images of a hologram are photographed. It is determined by set number determination whether the set number of images of the hologram have already been photographed (S203). If the actual number of images is less than the set number, the hologram photographing is performed (S202′), and if the set number is satisfied, the flow proceeds to the next step without performing the hologram photographing (S202′).

Next, the photographed holograms are stored, as hologram storage (S204), in the auxiliary storage unit 24 (see FIG. 1) such as a hard disk drive or a solid state drive.

Next, optical condition adjustment, etc., for the transmission electron microscope are performed (S205). Here, the optical condition adjustment, etc., 205 include correction of a focus deviation amount into a proper range, correction of astigmatism, correction of drift of an electron biprism, correction of illumination beam position, etc.

Finally, end determination is performed (S206), in which it is determined whether an end condition of the collection flow is satisfied. If it is satisfied, the collection flow ends, and if it not satisfied, the flow returns to the movement of field of view (S201) again and hologram collection is repeated.

In the related technology shown in FIG. 4, even if no particle is contained in the holograms collected in the hologram photographing (S202), or even if a very large number of particles are contained and the possibility that particles may be overlapped each other is very high, the hologram photographing (S202′) of a plurality of images is continued, and the hologram storage (S204) is performed.

When no particle is contained or particles are overlapped each other in a hologram, the hologram is unsuitable for the subsequent processing for the integration and averaging of particles. Therefore, the time for collecting these holograms and the stored date become useless. Further, in the data analysis processing performed subsequently, analysis processing is performed on the unnecessary images, which makes the analysis time useless.

In the image collection flow of the first embodiment shown in FIG. 3, an unnecessary image is determined by the particle determination (S210), and the subsequent hologram photographing (S202′) and hologram storage (S204) are not performed. Thereby, the time necessary for the hologram photographing (S202′) and the time necessary for storing the data into the auxiliary storage unit 24 can be reduced. As a result, the image collection time can be reduced as a whole, and the volume of stored data can be reduced.

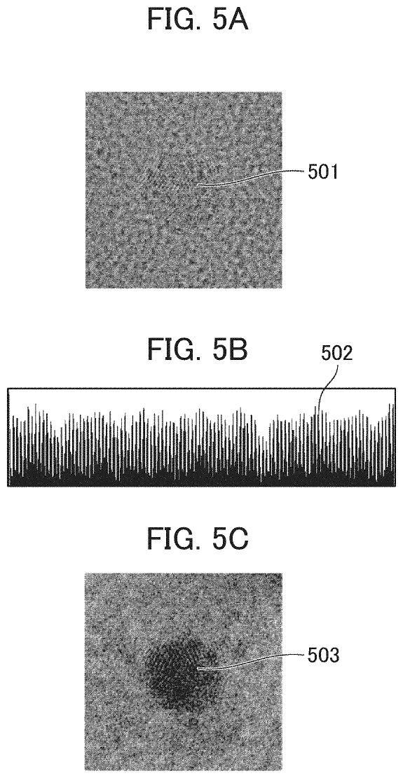

Hereinafter, a specific example of the particle determination (S210) shown in FIG. 3 will be described in detail. For the determination on whether a particle is contained in a hologram, there are two types of processing methods depending on whether an image is processed in a real space or a frequency space. First, processing in a general real space will be considered. FIG. 5A shows a hologram of a gold nanop article portion, FIG. 5B shows a line profile along the upper right to the lower right of FIG. 5A, and FIG. 5C shows a phase image reconstructed from the hologram of FIG. 5A.

In FIG. 5A, the contrast of a particle 501 is weak, so it is difficult to spatially separate the portion of the particle 501 in the image, that is, to distinguish the particle 501. This is because the amplitude contrast of an electron that has passed through is rarely created due to the small size (thin thickness) of the particle 501.

Then, an effort is to be made to increase the image contrast by image processing, but FIG. 5A shows a hologram, and hence on its contrast, the contrast of an interference fringe 502 is superimposed as shown in FIG. 5B, so that the contrast of the interference fringe 502 is also increased. Therefore, it is difficult to increase the contrast such that the particle 501 can be distinguished.

FIG. 5C is obtained by removing the contrast of the interference fringes 502 and by being subjected to reconstruction processing such that a phase contrast can be obtained. An image of the particle 503 whose contrast is clear is obtained, so that it becomes possible to distinguish the particle 503. However, a long processing time is necessary for two-dimensional phase unwrapping processing included in the phase reconstruction processing. For example, in the case of an image having a size of 3839 pixels×3711 pixels that was photographed in the first embodiment, a processing time of 20 seconds or more was necessary when a general image processing personal computer was used. Currently, one image is collected in about 3.5 seconds and an object of the present invention is to reduce a data collection time, and hence the above processing time is not acceptable. So, it must be said that it is difficult to determine whether a particle is present, by using a phase reconstruction image.

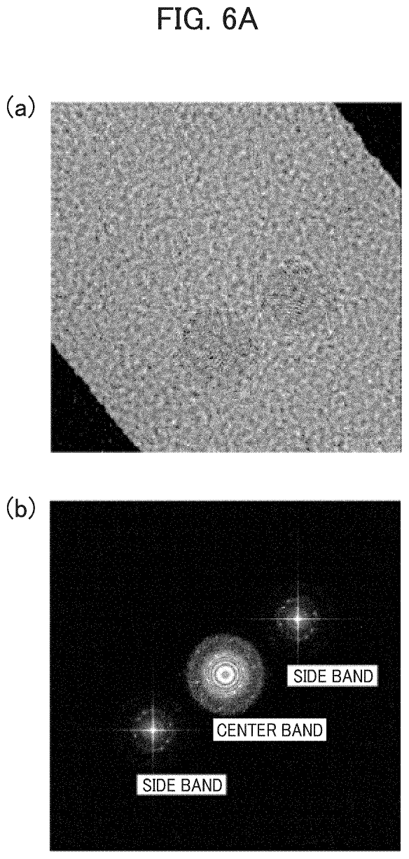

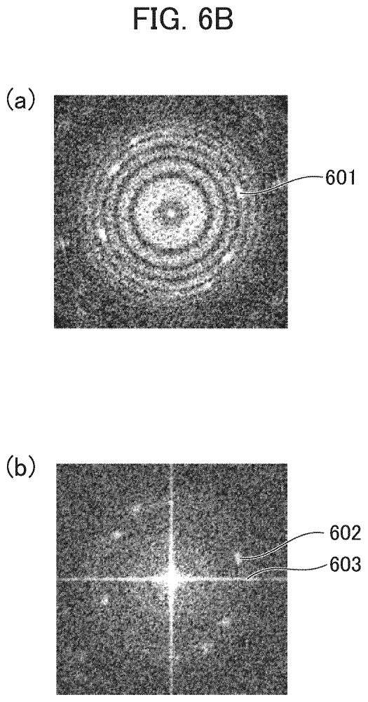

Then, the possibility that a particle may be detected in a spatial frequency space has been examined. When the hologram shown in (a) of FIG. 6A is subjected to discrete Fourier transform and made transition to a frequency space, a Fourier-transformed image as shown in (b) of FIG. 6A can be obtained. This Fourier-transformed image is separated into a complex number domain called center band and complex number domains called sideband.

In FIG. 6B, (a) and (b) are absolute values of the center band and the sideband, respectively, which are displayed as images. First, a way of specifying the domains of the center band and the sideband from the discrete Fourier transform of a hologram, and information included in each of the domains will be described by the following analysis expressions.

The object wave on the camera surface is defined by a first mathematical expression.

[First Mathematical Expression]

ϕ(r)exp[iζ(r)]⊗FT{exp[2πi×(g)]}·exp[2πik·r] (1)

The reference wave on the camera surface is defined by a second mathematical expression.

[Second Mathematical Expression]

exp[2πik′·r] (2)

where r, g, k, and k′ are a two-dimensional position vector, a two-dimensional spatial frequency vector, a wave number vector of the object wave, and a wave number vector of the reference wave, respectively. And, ϕ(r), ζ(r), and x(g) are amplitude modulation immediately after passing through the sample, phase modulation immediately after passing through the sample, and wave aberration by an imaging lens, respectively. FT{ } and (x) are operation symbols representing Fourier transform and convolution, respectively. When the interference created with the object wave and the reference wave overlapped each other is detected by a camera, electron interference fringes (hologram) as shown in (a) of FIG. 6A are obtained as an image. When this hologram is subjected to Fourier transform, a Fourier-transformed image as shown in (b) of FIG. 6A is obtained. This is separated into three domains represented by the following third mathematical expression.

[Third Mathematical Expression]

FT{1+|{ϕ(r)exp[ζ(r)]}⊗FT{exp[2πix(g)]}|²}+[FT{ϕ(r)exp[iζ(r)]}exp[2πix(g)]]⊗δ(g−K₀)+[FT{ϕ(r)exp[iζ(r)]}exp[−2πix(g)]]⊗δ(g+K₀) (3)

where k₀=k−k′. The first term represents the center band and the second and third terms each represents a sideband. The two sidebands have a conjugate relationship and are equivalent. The center band and the sideband are separated from each other in the spatial frequency space by k₀ (g=0: center of the center band, g=±k₀: center of the sideband), and a domain from the center of the sideband to radius |k₀|/3 is defined as the sideband domain, and a domain from the center of the center band to radius 2|k₀|/3 is defined as the center band domain.

Although each of the center band and the sideband is a complex number, it can be displayed as an image by taking its absolute value. When the sample is assumed to be a weak phase object and weak phase object approximation is performed in order to easily understand the meaning of the display, the object wave after passing through the sample is represented by a fourth mathematical expression.

[Fourth Mathematical Expression]

ϕ(r)exp[iζ(r)]≅1+iζ(r) (4)

Then, the center band is represented by a fifth mathematical expression.

[Fifth Mathematical Expression]

2|δ(g)−FT{ζ(r)}sin[2π×(g)]| (5)

The sidebands (one of the two) are (is) represented by a sixth mathematical expression.

[Sixth Mathematical Expression]

|FT{ζ(r)}| (6)

From these displays, (a) and (b) of FIG. 6B are obtained by cutting out domains having the same size. It is learned that in the center band, the variation in lens aberration (sin[2π×(g)], Thon ring pattern) is superimposed on the frequency component FT {ζ(r)} of the phase modulation by the sample. On the other hand, in the sideband, the frequency component FT {ζ(r)} of the phase modulation by the sample is only displayed.

That is, it has been learned that: if it is attempted to determine from the center band whether a particle is present, the Thon ring pattern is overlapped, so that detection of the information on the presence or absence of a particle is hampered; however, if it is determined by using the sideband whether a particle is present, the determination can be made without being hampered by the Thon ring pattern.

Since the gold nanoparticle used as a sample this time has a crystal structure, a spot that reflects the periodic structure of the crystal appears in the Fourier-transformed image. This corresponds to |FT{ζ(r)}|. Since the ring-shaped Thon pattern also appears strongly in (a) of FIG. 6B, it is difficult to determine by a gold crystal whether a spot 601 is present.

On the other hand, there is no ring pattern in (b) of FIG. 6B, and hence it is possible to determine whether a spot 602 is present. Although a cross pattern 603 contained in the sideband is an artifact following sampling an interference fringe discretely by pixels, the cross pattern 603 should be avoided when it is determined whether a spot is present.

The positions of the spots that have been created from the same crystal particles are distributed on concentric circles located at almost the same distance from the center of the side band. For example, in the case of a gold nanoparticle, spots are created at radial positions corresponding to spatial frequencies of 1/(0.24 nm) and 1/(0.20 nm). Therefore, by detecting a spot away from the center of the sideband by a distance corresponding to a preset spatial frequency, it is possible to determine whether a particle is present.

When a spot is created at a position located at a different radial position, there is a high possibility that a particle that is not a desired particle, such as one adhered due to contamination, etc., may be detected, so that the spot is excluded from the determination of the presence of the particle. Although a spot may be accidentally created by the noise contained in an image, the spot is excluded also in this case since there is a high possibility that the position of the spot may be different from a desired particle. The position of the center of the sideband corresponds to the intersection point of the cross pattern 603, but it is sufficient to select the brightest position in the side band image.

The larger the number of particles contained in a hologram, the larger the number of spots. When the number of particles becomes too large, particles are contained in both the object wave and the reference wave, so that there is a high possibility that a hologram in which two particle images are overlapped each other may be obtained. On the other hand, when no particle is contained in a hologram, a clear spot is not obtained, but there is a possibility that a change in the brightness of an image, which follows a fluctuation of an emitted electron beam created due to shot noise, etc., may be recognized as a spot. At this time, it is expected that the number of spots may increase dramatically.

In the hologram collection actually performed by the inventor, it has been confirmed that when the number of the detected spots is 20 or less and those spots are obtained within a set range, a particle is contained in every image. However, when the number of spots was 40, there were some cases where a particle was not contained in 33% of the images each containing spots within a set range. When it was determined only by the number of spots whether a particle is present and when it was excluded from the particle determination whether a spot is present at a set radial position, no particle was contained in 30% of the holograms even if the number of the detected spots was 20, and when the number of the detected spots was 40, no particle was contained in 60% of the holograms. That is, it has been learned that in order to detect whether a particle is present, it is desirable to determine by combining a radial position of spots and the number of the spots.

Finally, the method of detecting a spot, adopted in the first embodiment 1, will be described. First, for the absolute value image of a hologram that has been subjected to Fourier transform, an image in which the central portion of the center band and the left half (or right half) of the Fourier-transformed image are masked is prepared, and the brightest point in the image is found. This point becomes the center of the sideband. An area, ranging from the center of the sideband to one third of the distance between the center of the sideband and the center of the center band, is cut out, which is defined as the sideband image. After the central portion of the sideband image and the area of the cross pattern are masked, the brightest pixel is detected.

The size of the mask for the central portion of the side band is made about half the set spot radius. Pixels each having brightness from the brightest pixel value detected to half the brightness are listed. The brightness of each of the listed pixels is compared with those of eight pixels around the each pixel, and if the brightness of every around-pixel is lower than that of the each pixel, it is determined that the each pixel is located at a peak position, whereby the point is detected as a spot. All the above processing is performed by the particle determination unit 23 of FIG. 1. For example, the particle determination unit 23 determines whether it is necessary to acquire an image, based on the distance from the center or the number of particles that is received from a user.

As described above, the particle determination unit 23 determines whether a particle is present, by acquiring a sideband image in the Fourier space of an observation image. Specifically, the photographing unit (camera 12) photographs an image of the electron interference fringes 13, and the particle determination unit 23 calculates the Fourier-transformed image of the image of the electron interference fringes 13, so that a sideband image is extracted from the Fourier-transformed image. The particle determination unit 23 determines whether a particle is present within the observation field of view, by using the image intensity peak position and image intensity peak number of the sideband image.

### Second Embodiment

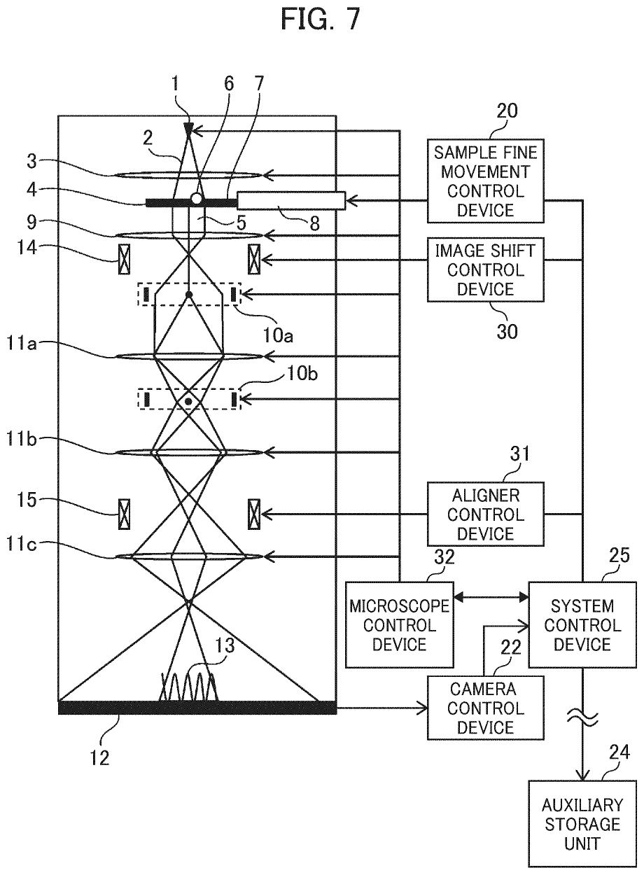

With reference to FIG. 7, a configuration of an image collection system using a transmission electron microscope according to a second embodiment will be described. Although the basic configuration of the transmission electron microscope is the same as FIG. 1, more practical holography observation can be made by mounting the two electron biprisms 10 (10a, 10b) so as to configure a double biprism interferometer. Two units of the sample fine movement device 8 and the image shift deflector 14 are provided to move field of view, and in order to control them, the sample fine movement control device 20 and the image shift control device 30 are provided.

The movement of field of view using the image shift deflector 14 is characterized by being performed at high speed and having low drift, and is utilized in high-magnification observation. The illumination position of an electron beam to irradiate a sample may be moved in conjunction with the movement of field of view. The movement of field of view using the sample fine movement device 8 is characterized by having a large moving distance. And, it is also characterized by having a small change in an image when an optical condition is changed, since it is not necessary to move the illumination position of an electron beam to be irradiated. When movement of field of view is performed by combining the sample fine movement device 8 and the image shift deflector 14, movement at high speed and movement over a large moving distance can be both achieved.

A control device is functionally divided roughly into a microscope control device 32 for operating the electron microscope and a system control device 25 for operating the collection system for transmission electron microscope images. Respective control signals are transmitted to each other by communication.

The microscope control device 32 controls an electron gun 1, an illumination lens 2, the objective lens 9, the electron biprisms 10, and the magnifying lenses 11 in order to set basic conditions for the transmission electron microscope to collect images. Also, the microscope control device 32 receives a signal from a system control device 25 and performs the optical condition adjustment, etc., 205. For example, the microscope control device 32 changes an exciting current of the objective lens 9 and adjusts the focus of an image to be collected into a proper range.

In order to achieve the flow shown in FIG. 3, the system control device 25 performs the movement of field of view (S201) by controlling the sample fine movement control device 20 and the image shift control device 30, performs the hologram photographing (S202) by controlling the camera control device 22, and performs the optical condition adjustment, etc. (S205) by controlling an aligner control device 31.

The particle determination (S210) is achieved by a function obtained by integration into the system control device 25. The system control device 25 determines whether a sample object 6 is present by analyzing a hologram image received from the camera control device 22, and performs the movement of field of view (S201) and the hologram photographing (S202). The hologram storage (S204) is also controlled by the system control device 25, and the holograms can be transferred to the auxiliary storage unit 24 installed in a remote place via a network.

### Third Embodiment

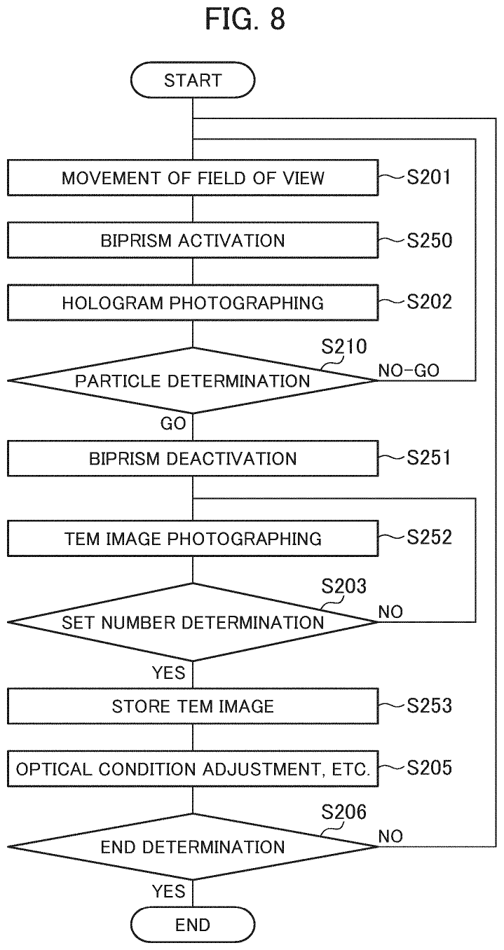

A third embodiment will be described with reference to FIG. 8 and FIG. 7.

FIG. 8 shows a flow for collecting a large number of transmission electron microscope images (TEM images), not holograms. This flow is controlled in time series by the system control device 25 of the image collection system using the transmission electron microscope shown in FIG. 7.

A sample is placed in the transmission electron microscope, initial adjustment work for the transmission electron microscope is then performed by the microscope control device 32, and an observation site of the sample is then determined, and thereafter movement of field of view is performed at first (S201) according to the flow shown in FIG. 8. The sample is divided into a grid pattern, and it is moved such that its one division can be sequentially observed. The movement is performed by horizontal raster scan, vertical raster scan, or spiral scan in a spiral manner. The movement of field of view (S201) is performed by the sample fine movement device 8, the image shift deflector 14, or by both of them.

Next, biprism activation is performed (S250) by applying a voltage to the electron biprism 10, thereby overlapping each other the object wave 5 and the reference wave 4 on the camera 12.

Next, hologram photographing is performed (S202). The reason why hologram photographing is performed here is because it is made easy to determine whether a particle is contained within a field of view. That is, it is because it is possible to determine whether a particle is present by subjecting a hologram to discrete Fourier transform and extracting its sideband domain, without being hampered by a Thon ring pattern due to lens aberration, as shown in (b) of FIG. 6B.

When it is performed to determine whether a particle is present by using a TEM image as it is, instead of a hologram, a Fourier-transformed image of the TEM image is calculated, but this has a pattern equivalent to the center band (see (a) of FIG. 6B) of the Fourier-transformed image of a hologram. Therefore, a Thon ring pattern is superimposed, and hence it is difficult to determine whether a particle is present. A method of extracting a sideband and a method of performing particle determination from the extracted sideband may be the same as the first embodiment.

Next, biprism deactivation is performed (S251), so that the overlap of the object wave 5 and the reference wave 4 is eliminated. At this time, the shadow of the deactivated biprism appears within the field of view, but in order to remove this shadow, it may be deflected by an aligner deflector 15 outside the field of view so as not to appear.

Next, TEM image photographing is repeatedly performed the set number of times (S252). When it is determined by the set number determination (203) that the set number of TEM images have been collected, the TEM images are stored in the auxiliary storage unit 24 (S253). These steps are performed by the control of the system control device 25.

If necessary, the optical condition adjustment, etc. (S205) is performed, and thereafter end determination of the TEM image collection flow is performed (S206). If the result of the determination is No, the movement of field of view (S201) is performed again so as to repeat the collection, while the result is Yes, the flow is ended.

In the image collection system using the transmission electron microscope according to the third embodiment, the photographing unit (camera 12) acquires the overlapped electron waves as an image of the electron interference fringes 13, as described above. The control unit (system control device 25) determines whether a particle is present within an observation field of view, by using the image of the electron interference fringes 13. Based on a result of determining whether a particle is present within the field of view, the control unit determines whether it is necessary to store the image.

When it is necessary to store the image as a result of the determination on whether it is necessary to store the image, the photographing unit (camera 12) acquires a transmission electron microscope image (TEM image) within the observation field of view, and the control unit (system control device 25) stores the acquired transmission electron microscope image (TEM image) in the storage unit (auxiliary storage unit 24).

According to the above embodiments, a function of determining whether a particle is present is provided, and hence photographing an observation field of view that is unsuitable for photographing can be prevented. Thereby, an image collection time can be reduced as a whole.

What is claimed is:

1. An image collection system using a transmission electron microscope, the image collection system comprising:
a control unit that moves an observation field of view in the transmission electron microscope;
a photographing unit that acquires an observation image by overlapping each other electron waves that have passed through the observation field of view with the use of the transmission electron microscope; and
a determination unit that determines whether a particle is present within the observation field of view,
wherein the determination unit determines whether the particle is present, by acquiring a sideband image in Fourier space of the observation image.

2. The image collection system according to claim 1,
wherein the photographing unit photographs an electron interference fringe image, and
wherein the determination unit calculates a Fourier-transformed image of the electron interference fringe image, and extracts the sideband image from the Fourier-transformed image.

3. The image collection system according to claim 2,
wherein the determination unit determines whether the particle is present within the observation field of view, by using an image intensity peak position and an image intensity peak number of the sideband image.

4. The image collection system according to claim 1,
wherein the determination unit determines whether it is necessary to acquire the observation image by the photographing unit, based on a result of determining whether the particle is present within the observation field of view.

5. The image collection system according to claim 1,
wherein the determination unit determines whether it is necessary to store the observation image, based on a result of determining whether the particle is present within the observation field of view.

6. An image collection system using a transmission electron microscope, the image collection system comprising:
a control unit that moves an observation field of view in the transmission electron microscope in order to overlap each other electron waves that propagate through spatially different portions within the observation field of view;
a photographing unit that acquires the overlapped electron waves as an observation image; and
a determination unit that determines whether a particle is present within the observation field of view.

7. The image collection system according to claim 6,
wherein the determination unit determines whether it is necessary to acquire the observation image by the photographing unit, based on a result of determining whether the particle is present within the observation field of view.

8. The image collection system according to claim 6,
wherein the determination unit determines whether it is necessary to store the observation image, based on a result of determining whether the particle is present within the observation field of view.

9. An image collection system using a transmission electron microscope, the image collection system comprising:
a control unit that moves an observation field of view in the transmission electron microscope, overlaps each other electron waves that propagate through spatially different portions within the observation field of view, and determines whether a particle is present within the observation field of view;
a photographing unit that acquires an image; and
a storage unit that stores the acquired image,
wherein the photographing unit acquires the overlapped electron waves as an electron interference fringe image,
wherein the control unit determines whether the particle is present within the observation field of view, by using the electron interference fringe image, and determines whether it is necessary to store the image based on a result of determining whether the particle is present within the observation field of view, and
wherein when it is necessary to store the image as a result of determining whether it is necessary to store the image, the photographing unit acquires a transmission electron microscope image within the observation field of view, and the control unit stores the acquired transmission electron microscope image in the storage unit.

10. The image collection system according to claim 9,
wherein the control unit calculates a Fourier-transformed image of the electron interference fringe image, and extracts a sideband image from the Fourier-transformed image.

11. The image collection system according to claim 10,
wherein the control unit determines whether the particle is present within the observation field of view, by using an image intensity peak position and an image intensity peak number of the sideband image.

12. The image collection system according to claim 9, further comprising an image shift deflector,
wherein the control unit moves the observation field of view by using the image shift deflector.
